(19) United States
(12) Patent Application Publication
(10) Pub. No.: US 2023/0229731 A1
(43) Pub. Date: Jul. 20, 2023

(54) DATA PROCESSING SYSTEM, OPERATING METHOD THEREOF, AND COMPUTING SYSTEM USING THE SAME

(71) Applicant: SK hynix Inc., Gyeonggi-do (KR)

(72) Inventor: Sangeun JE, Gyeonggi-do (KR)

(21) Appl. No.: 18/094,987

(22) Filed: Jan. 10, 2023

(30) Foreign Application Priority Data
Jan. 20, 2022 (KR) 10-2022-0008499

(51) Int. Cl. G06F 17/16; G06F 7/487; G11C 7/16

(52) U.S. Cl. CPC G06F 17/16; G06F 7/4876; G11C 7/16

(57) ABSTRACT

A data processing system may include: a matrix splitting circuit configured to: split the matrix into a positive matrix and a negative matrix, and store the positive matrix and the negative matrix in a first sub array and a second sub array within the computation memory, respectively; a vector conversion circuit configured to generate an offset vector by adding, to elements within the vector, an offset for converting a negative element, which has a largest absolute value among the elements within the vector, into a zero element or a positive element, and apply the offset vector to the row lines of the first sub array and the second sub array; and an offset correction circuit configured to generate an offset correction value by subtracting a result of multiplying the offset and the negative matrix from a result of multiplying the offset and the positive matrix, and subtract the offset correction value from a computation value outputted from the first sub array and the second sub array,

### CROSS-REFERENCES TO RELATED APPLICATION

The present application claims priority under 35 U.S.C. § 119(a) to Korean patent application number 10-2022-0008499, filed on Jan. 20, 2022, which is incorporated herein by reference in its entirety.

### BACKGROUND

### 1. Technical Field

Various embodiments of the present disclosure generally relate to a data processing technology, and more particularly, to a data processing system, an operating method thereof, and a computing system using the same.

### 2. Related Art

As much attention is paid to Artificial Intelligence (AI) applications and big data analysis while the importance thereof is increased, there is an increasing demand for a computing system capable of efficiently processing big data.

An artificial neural network is one method for implementing AI. Computations performed by AI applications are mainly composed of vector-matrix multiplications, and research is being conducted on various methods for accurately computing an enormous volume of data at high speed.

### SUMMARY

In an embodiment of the present disclosure, a data processing system may include: a computation memory comprising one or more sub arrays each including a plurality of memory cells coupled between a plurality of row lines and a plurality of column lines; a matrix splitting circuit configured to: split, when negative elements are included in a matrix received from a host device, the matrix into a positive matrix composed of positive elements from the matrix and a negative matrix composed of absolute values of the negative elements from the matrix, and store the positive matrix and the negative matrix in a first sub array and a second sub array within the computation memory, respectively; a vector conversion circuit configured to: generate, when negative elements are included in a vector received from the host device, an offset vector by adding, to elements within the vector, an offset for converting a negative element, which has a largest absolute value among the elements within the vector, into a zero element or a positive element, and apply the offset vector to the row lines of the first sub array and the second sub array; and an offset correction circuit configured to: generate an offset correction value by subtracting a result of multiplying the offset and the negative matrix from a result of multiplying the offset and the positive matrix, and subtract the offset correction value from a computation value outputted from the first sub array and the second sub array.

In an embodiment of the present disclosure, an operating method of a data processing system may include providing a computation memory comprising one or more sub arrays each including a plurality of memory cells coupled between a plurality of row lines and a plurality of column lines; splitting, by a negative number computation control circuit, when negative elements are included in a matrix received from a host device, the matrix into a positive matrix composed of positive elements from the matrix and a negative matrix composed of absolute values of the negative elements from the matrix; storing the positive matrix and the negative matrix in a first sub array and a second sub array within the computation memory, respectively; generating, by the negative number computation control circuit, when negative elements are included in a vector received from the host device, an offset vector by adding, to elements within the vector, an offset for converting a negative element, which has a largest absolute value among the elements within the vector, into a zero element or a positive element; applying, by the negative number computation control circuit, the offset vector to the row lines of the first sub array and the second sub array; generating, by the negative number computation control circuit,an offset correction value by subtracting a result of multiplying the offset and the negative matrix from a result of multiplying the offset and the positive matrix; and subtracting, by the negative number computation control circuit, the offset correction value from a computation value outputted from the first and second sub arrays.

In an embodiment of the present disclosure, a computing system may include: a host device; a data processing system configured to process a computation of an application according to a request of the host device, and comprising a computation memory including one or more sub arrays each including a plurality of memory cells coupled between a plurality of row lines and a plurality of column lines; and a negative number computation control circuit configured to split, when negative elements are included in a matrix received from the host device, the matrix into a positive matrix and a negative matrix, generate, when negative elements are included in a vector received from the host device, an offset vector by adding an offset to the vector, and correct a computation value, outputted as a result of multiplying each of the positive and negative matrices with the offset vector, from the computation memory according to an offset correction value generated on the basis of the offset.

In an embodiment of the present disclosure, an operating method of an in-memory computation device may include generating, by adding an adjusting vector to a provided vector, an offset vector comprising non-negative elements; converting a provided matrix into positive and negative matrixes to program the positive and negative matrixes respectively into first and second memristor memory cell arrays; generating positive and negative computation vectors by applying offset signals on respective rows of the respective first and second arrays and summing, on a column basis, results of the applying of the offset signals, the offset signals representing the respective elements of the offset vector; generating an intermediate vector by subtracting the negative computation vector from the positive computation vector; generating positive and negative correction vectors by applying an adjusting signal on the rows of the respective first and second arrays and summing, on a column basis, results of the applying of the adjusting signal, the adjusting signal representing a single value that every element has within the adjusting vector; generating an offset correction vector by subtracting the negative correction vector from the positive correction vector; and generating a result vector by subtracting the offset correction vector from the intermediate vector, wherein: the provided vector is of a [1×N] dimension, where N is an integer greater than 0, each of the provided, positive and negative matrixes and the first and second arrays is of a [N×M] dimension, where M is an integer greater than 0, the positive matrix comprises positive elements from the provided matrix and one or more zero elements, and the negative matrix comprises absolute-value elements of negative elements from the provided matrix and one or more zero elements.

### BRIEF DESCRIPTION OF THE DRAWINGS

FIG. 1 is a configuration diagram illustrating a computing system in accordance with an embodiment of the present disclosure.

FIG. 2 is a configuration diagram illustrating a neural network processor in accordance with an embodiment of the present disclosure.

FIG. 3 is a configuration diagram illustrating a computation memory in accordance with an embodiment of the present disclosure.

FIG. 4 is a configuration diagram illustrating a negative number computation control circuit in accordance with an embodiment of the present disclosure,

FIG. 5 is a flowchart for describing an operating method of a data processing system in accordance with an embodiment of the present disclosure of the present disclosure.

FIGS. 6A to 6E are conceptual views for describing a VMM (Vector-Matrix Multiplication) including negative numbers in accordance with an embodiment of the present disclosure.

FIG. 7 is a conceptual view for describing an offset correction value generation method in accordance with an embodiment of the present disclosure.

FIG. 8 is a configuration diagram illustrating a negative number computation control circuit in accordance with an embodiment of the present disclosure,

FIG. 9 is a configuration diagram illustrating a processing element in accordance with an embodiment of the present disclosure.

FIGS. 10A to 10E are conceptual views for describing an offset vector providing method in accordance with an embodiment of the present disclosure.

FIG. 11 is a flowchart for describing an operating method of a data processing system in accordance with an embodiment of the present disclosure.

### DETAILED DESCRIPTION

Hereafter, embodiments of the present disclosure will be described in more detail with reference to the accompanying drawings.

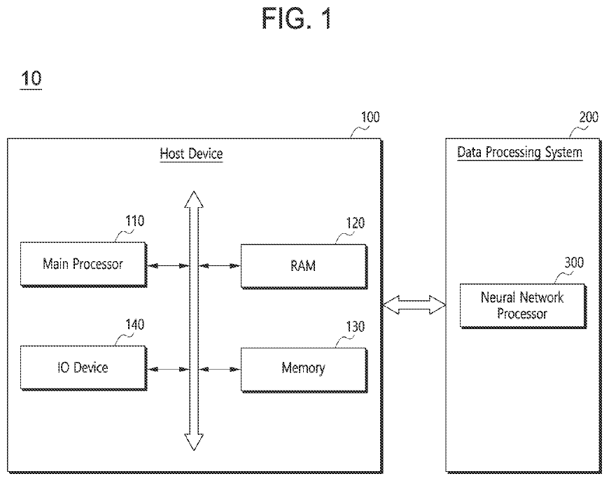

FIG. 1 is a configuration diagram illustrating a computing system in accordance with an embodiment of the present disclosure.

Referring to FIG. 1, a computing system 10 in accordance with an embodiment may include a host device 100 and a data processing system 200. The data processing system 200 may include a neural network processor 300 configured to process a computation of an application according to a request of the host device 100.

The host device 100 may at least include a main processor 110, a RAM 120, a memory 130, and an Input/Output (I/O) device 140, and further include other general-purpose components (not illustrated).

In an embodiment, the components of the host device 100 may be integrated as one semiconductor chip and implemented as System on Chip (SoC). However, the embodiment is not limited thereto, but the components of the host device 100 may be implemented as a plurality of semiconductor chips.

The main processor 110 may control overall operations of the computing system 10. For example, a Central Processing Unit (CPU) may serve as the main processor 110. The main processor 110 may include one or more cores. The main processor 110 may process or execute programs, data, or instructions stored in the RAM 120 and the memory 130. For example, the main processor 110 may control the functions of the computing system 10 by executing the programs stored in the memory 130.

The RAM 120 may temporarily store programs, data, or instructions. The programs and/or data stored in the memory 130 may be temporarily loaded to the RAM 120 according to a booting code or under control of the main processor 110. The RAM 120 may be implemented as a memory such as a Dynamic RAM (DRAM) or Static RAM (SRAM),

The memory 130 may serve as a storage place for storing data, e.g., an Operating System (OS), various programs, and various data, The memory 130 may include one or more of a volatile memory and a non-volatile memory. The non-volatile memory may be selected from a Read Only Memory (ROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), Ferroelectric RAM (FRAM) and the like, The volatile memory may be selected from a DRAM, SRAM, Synchronous DRAM (SDRAM) and the like. In an embodiment, the memory 130 may be implemented as a storage device such as a Hard Disk Drive (HDD), Solid-State Drive (SSD), Compact Flash (CF), Secure Digital (SD), Micro Secure Digital (Micro-SD), Mini Secure Digital (Mini-SD), extreme digital (xD), or memory stick.

The I/O device 140 may receive a user input or input data from the outside, and output a processing result of the computing system 10. The I/O device 140 may be implemented as a touch screen panel, keyboard, or various types of sensors. In an embodiment, the I/O device 140 may collect information around the computing system 10. For example, the I/O device 140 may include an imaging device and an image sensor, sense or receive an image signal from the outside of the computing system 10, convert the sensed or received image signal into image data, and store the image data in the memory 130 or provide the image data to the data processing system 200.

The data processing system 200 may process a computation of an application in response to a request of the host device 100, In particular, the data processing system 200 may extract valid information by analyzing input data on the basis of an artificial neural network, and determine a situation on the basis of the extracted information or control components of an electronic device in which the data processing system 200 is mounted. For example, the data processing system 200 may be applied to a drone, Advanced Drivers Assistance System (ADAS), smart TV, smart phone, medical device, mobile device, image display device, measurement device, Internet of Things (IoT) device and the like. In addition, the data processing system 200 may be mounted on any of various types of computing systems 10.

In an embodiment, the host device 100 may offload a neural network computation onto the data processing system 200, and provide the data processing system 200 with initial parameters for the neural network computation, for example, an input vector and a weight matrix.

In an embodiment, the data processing system 200 may be an application processor mounted in a mobile device.

The data processing system 200 may at least include the neural network processor 300.

The neural network processor 300 may generate a neural network model by training or learning input data, generate an information signal by inferring input data according to the neural network model, or retrain the neural network model. The neural network may include various types of neural network models such as a Convolution Neural Network (CNN), Region with Convolution Neural Network (R-CNN), Region Proposal Network (RPN), Recurrent Neural Network (RNN), Stacking-based deep Neural Network (S-DNN), State-Space Dynamic Neural Network (S-SDNN), deconvolution network, Deep Belief Network (DBN), Restricted Boltzmann Machine (RBM), fully convolutional network, Long Short-Term Memory (LSTM) network, and classification network, but is not limited thereto.

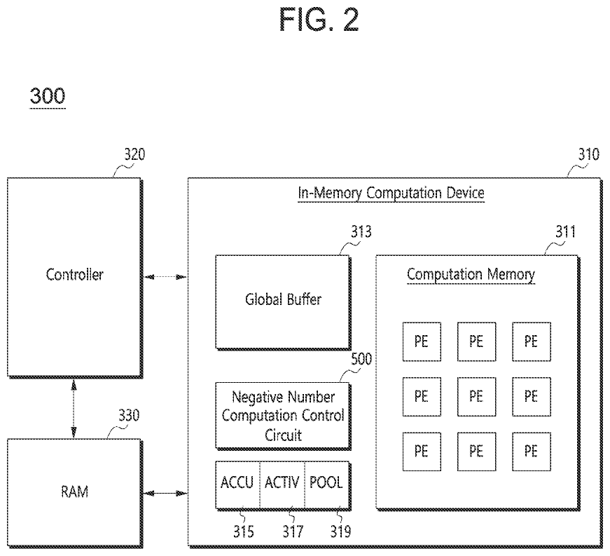

FIG. 2 is a configuration diagram illustrating a neural network processor in accordance with an embodiment of the present disclosure.

The neural network processor 300 may be a processor or accelerator specialized for neural network computation, and include an in-memory computation device 310, a controller 320, and a RAM 330, as illustrated in FIG. 2. In an embodiment, the neural network processor 300 may be implemented as SoC which is integrated as one semiconductor chip. However, the embodiment is not limited thereto, but the neural network processor 300 may be implemented as a plurality of semiconductor chips.

The controller 320 may control overall operations of the neural network processor 300. The controller 320 may set and manage parameters related to neural network computation such that the in-memory computation device 310 can normally perform neural network computation. The controller 320 may be implemented in hardware, software (firmware) or a combination of hardware and software,

The controller 320 may be implemented as one or more processors, for example, a Central Processing Unit (CPU), micro processor or the like, and execute instructions constituting various functions stored in the RAM 330.

As the host device 100 offloads a neural network computation onto the neural network processor 300 by transmitting an operand including a vector and matrix to the neural network processor 300, the controller 320 may transmit the operand and an address, at which the operand is to be stored, to the in-memory computation device 310.

The RAM 330 may be implemented as a DRAM, SRAM or the like, and temporarily store various programs and data for an operation of the controller 320 and data generated by the controller 320.

The in-memory computation device 310 may be configured to perform the neural network computation under control of the controller 320, The in-memory computation device 310 may include a computation memory 311, a global buffer 313, an accumulation circuit (ACLU) 315, an activation circuit (ACTIV) 317, a pooling circuit (POOL) 319 and a negative number computation control circuit 500,

The computation memory 311 may include a plurality of processing elements PE. The processing elements PE may each receive a vector and matrix as operands from the global buffer 313, and perform a Vector-Matrix Multiplication (VMM). In an embodiment, the vector may be an input feature map of the neural network computation, and the matrix may be a weight matrix.

Each of the processing elements PE may include a plurality of sub arrays. Each of the sub arrays may include a plurality of memory cells coupled between a plurality of row lines and a plurality of column lines. For the neural network computation, the weight matrix serving as a first operand may be stored in memory cells of the sub arrays, and a vector corresponding to the input feature map and serving as a second operand may be applied to row lines of the sub arrays. Then, an in-memory computation, for example, VMM may be performed. The VMM may be a convolution computation, for example, a multiplication and addition for each element. In an embodiment, the first operand may be an NxM matrix, and the second operand may be an 1xN vector. Here, N and M each are positive integers.

In an embodiment, the sub array may be a cross-bar array of a memory device including mernristor elements. The sub array may be programmed so that memristor memory cells arranged at intersections of the cross-bar array have conductances corresponding to the respective element values of the matrix, and the elements of the vector may be converted into analog input voltages, and the analog input voltages may be applied to the row lines. Therefore, the input voltages applied to the respective rove lines of the cross-bar array may be increased by the conductances of the memristor memory cells, and accumulated and outputted as current values for the respective column lines.

The global buffer 313 may store the operands therein, and then provide the stored operands to the computation memory 311. Furthermore, the global buffer 313 may receive a computation result from the computation memory 311, and store the received computation result therein. The global buffer 313 may be implemented as a DRAM or SRAM,

The accumulation circuit 315 may be configured to derive a weighted sum by accumulating the processing results of the respective processing elements PE.

The activation circuit 317 may be configured to add non-linearity by applying the weighted sum of the accumulation circuit 315 to an activation function such as ReLU,

The pooling circuit 319 may sample an output value of the activation circuit 317, and reduce and optimize the dimension.

The process through the computation memory 311, the accumulation circuit 315, the activation circuit 317, and the pooling circuit 319 may indicate a process of training or retraining a neural network model or inferring input data.

When an operand transmitted from the host device 100 or an operand generated in an intermediate process of the neural network computation includes a negative element, the negative number computation control circuit 500 may convert the negative element into a non-negative element, i.e., a zero element or a positive element, and store the operand including the converted non-negative dement in the global buffer 313,

In an embodiment, when a negative dement is included in the matrix serving as the first operand, the negative number computation control circuit 500 may split the elements constituting the matrix into a positive matrix composed of positive dements and a negative matrix composed of the absolute values of negative elements, and store the positive matrix and the negative matrix in the global buffer 313, The positive matrix and the negative matrix, stored in the global buffer 313, may be separately stored in a first sub array and a second sub array, respectively,

In an embodiment, when a negative dement is included in the vector serving as the second operand, the negative number computation control circuit 500 may generate an offset vector by adding, to each of the dements of the vector, an offset for converting the negative element having the largest absolute value among the elements of the vector into a non-negative element, and may apply the offset vector to row lines of the first and second sub arrays, in which the positive matrix and the negative matrix are respectively stored.

The computation memory 311 may perform a VMM on the operand including the converted non-negative dement, and store the VMM result in the global buffer 313.

When the computation memory 311 performs the VMM on a matrix including negative elements and a vector including negative elements, the computation memory 311 may store the positive matrix in the first sub array of the processing element PE, and apply the offset vector to the row lines of the first sub array to output a positive computation value, Furthermore, the computation memory 311 may store the negative matrix in the second sub array, and apply the offset vector to the row lines of the second sub array to output a negative computation value. Since the VMM has been performed on the absolute value of the negative element included in the matrix, the computation memory 311 combines the computation results by subtracting the negative computation value from the positive computation value.

When the VMM is performed through the offset value obtained by applying the offset to the vector, the negative number computation control circuit 500 may derive a final computation result by correcting the VMM result according to the offset, For example, the negative number computation control circuit 500 may calculate a first correction value as the result of VMM between the offset and the positive matrix and a second correction value as the result of VMM between the offset and the negative matrix, and derive an offset correction value by subtracting the second correction value from the first correction value. Then, the negative number computation control circuit 500 may acquire the final computation result by subtracting the offset correction value from the combined computation result, In an embodiment, each of the first and second sub arrays may be an array of [N×M] and the above-mentioned parameters may have dimensions as follows.

| PARAMETER | DIMENSION |
|---|---|
| positive matrix | matrix of [N × M] |
| negative matrix | matrix of [N × M] |
| offset | vector of [1 × N] |
| offset vector | vector of [1 × N] |
| positive computation value | vector of [1 × M] |
| negative computation value | vector of [1 × M] |
| computation resuit | vector of [1 × M] |
| first correction value | vector of [1 × M] |
| second correction value | vector of [1 × M] |
| offset correction value | vector of [1 × M] |

The computation memory configured as a cross-bar array using memristor memory cells stores a matrix as conductances in memory cells and applies a vector as voltages to row lines, and performs the VMM on the basis of the principle that currents corresponding to the products of the voltages and the conductances are added up for each column line. That is, it is impossible to perform the VMM on negative elements because the conductances and the voltages are used to perform an analog computation.

In accordance with an embodiment, however, a matrix including negative elements is split into a positive matrix and a negative matrix including the absolute values of the negative dements, the negative elements are converted into non-negative dements according to an offset in order to perform VMM, and the VMM results are combined and corrected. Therefore, even when a negative dement is included in the matrix or an operand, in-memory computation can be performed in an analog manner.

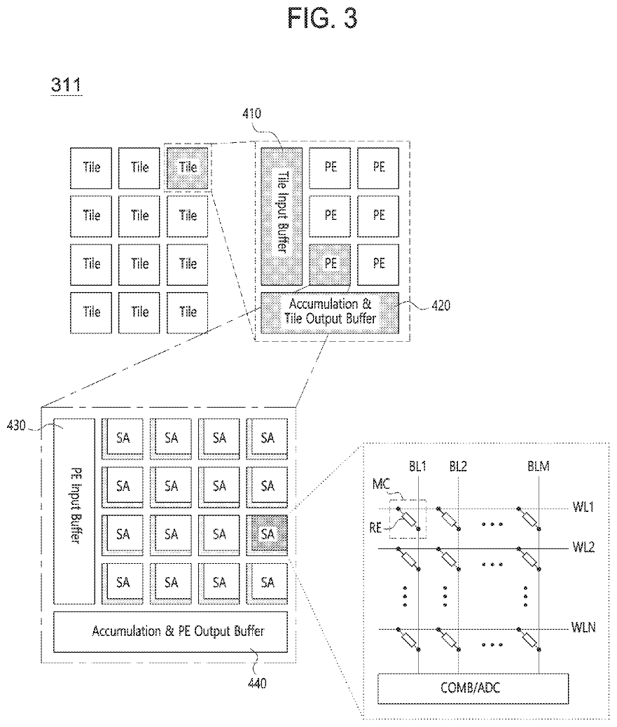

FIG. 3 is a configuration diagram illustrating a computation memory in accordance with an embodiment of the present disclosure,

Referring to FIG, 3, the computation memory 311 in accordance with an embodiment may be divided into a plurality of tiles.

Each of the tiles may include a tile input buffer 410, a plurality of processing elements PE, and a tile output buffer 420,

Each of the processing elements PE may include a PE input buffer 430, a plurality of sub arrays SA, and an accumulation/PE output buffer 440,

The sub array SA may also be referred to as a synapse array, and include a plurality of word lines WL1, WL2, . . . , WLN, a plurality of bit lines BL1, BL2, . . . , BLM, and a plurality of memory cells MC. The word lines WL1, WL2, . . . , WLN may also be referred to as row lines, and the bit lines BL1, BL2, BLM may also be referred to as column lines. In an embodiment, the memory cells MC may each include a resistive memory element RE, or desirably a memristor element. However, the embodiment is not limited thereto. Conductances, that is, data values stored in the memory cells MC, may be changed by write voltages applied through the word lines WL1, WLN and the bit lines BL1, BL2, . . . , BLM, and the resistive memory cells may store data through such a resistance change.

In an embodiment, each of the resistive memory cells may be implemented as a Phase change Random Access Memory (PRAM) cell, Resistance Random Access Memory (RRAM) cell, Magnetic Random Access Memory (MRAM) cell, or Ferroelectric Random Access Memory (FRAM) cell.

Examples of the resistive element constituting the resistive memory cell may include a phase-change material, perovskite compounds, transition metal oxide, magnetic materials, ferromagnetic materials or antiferromagnetic materials, whose crystalline states change according to the amount of current, but are not limited thereto.

As the unit cells of the sub array SA are configured as memristor elements, the processing element PE may store data corresponding to the respective elements of the weight matrix in the memristors, apply voltages corresponding to the respective elements of the input feature map to the word lines WL1, WL2, . . . , WLN, and perform the VMM by utilizing Kirchhoff's Current Law and Ohms' law.

Each of the bit lines BL1, BL2, . . . , BLM may also be referred to as an output channel, and coupled to a combiner/analog-digital converter (COMB/ADC). The COMB/ADC may sense VMM results applied to the bit lines BL1, BL2, . . . , BLM, and output the sensed results as digital values.

In particular, when a matrix including negative elements is split into a positive matrix and a negative matrix such that the positive matrix and the negative matrix are processed in different sub arrays SA, respectively, a positive computation value and a negative computation value may be converted into digital values by the COMB/ADC, and then the digital values may be combined through subtraction by a digital subtractor. Specifically, the negative computation value may be converted into a complementary number of 2, and the complementary number may be added to the negative computation value and combined with the positive computation value.

In an embodiment, the COMB/ADC may perform subtraction on the positive computation value and the negative computation value through an analog subtractor, and then convert the resultant value into a digital value.

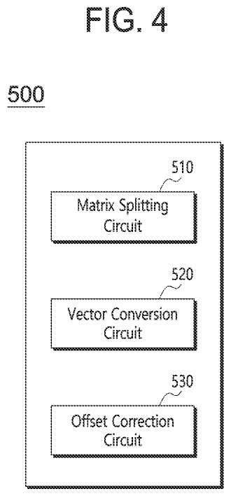

FIG. 4 is a configuration diagram illustrating a negative number computation control circuit in accordance with an embodiment of the present disclosure,

Referring to FIG. 4, the negative number computation control circuit 500 may include a matrix splitting circuit 510, a vector conversion circuit 520, and an offset correction circuit 530,

When the first operand which is a matrix generated as an intermediate computation result of the host device 100 or the computation memory 311 includes negative elements, the matrix splitting circuit 510 may split the elements constituting the matrix into a positive matrix composed of positive elements and a negative matrix composed of the absolute values of negative elements, and store the positive matrix and the negative matrix in the global buffer 313.

When negative elements are included in the vector serving as the second operand, the vector conversion circuit 520 may decide an offset for converting the negative element, which has the largest absolute value among the elements of the vector, into a non-negative element, and add the offset to each of the elements of the vector, thereby generating an offset vector.

As the offset is determined by the vector conversion circuit 520, the offset correction circuit 530 may calculate a first correction value as the VMM result between the positive matrix and the offset and a second correction value as the VMM result between the negative matrix and the offset, and derive an offset correction value by subtracting the second correction value from the first correction value. As a positive computation value acquired by the positive matrix and the offset vector and a negative computation value acquired by the negative matrix and the offset vector are combined and outputted by the computation memory 311, the offset correction circuit 530 may calculate the final computation result by subtracting the offset correction value from the combined computation result.

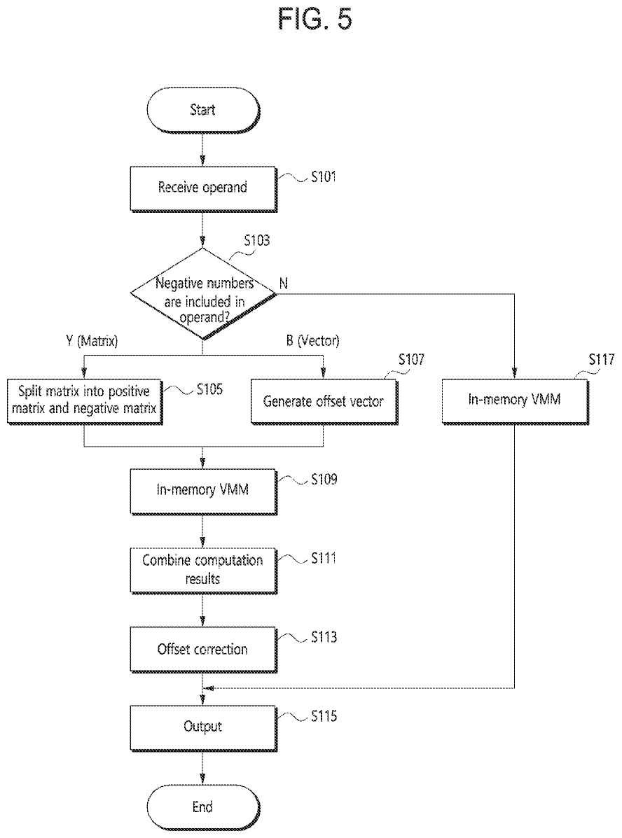

FIG. 5 is a flowchart for describing an operating method of a data processing system in accordance with an embodiment of the present disclosure.

As a first operand and a second operand are provided to the neural network processor 300 of the data processing system 200 in operation S101, the negative number computation control circuit 500 may check whether a negative element is included in the first operand and/or the second operand, in operation S103.

When a negative element is included in a matrix serving as the first operand (Y (matrix) in operation S103), the negative number computation control circuit 500 may split the elements constituting the matrix into a positive matrix composed of positive elements and a negative matrix composed of the absolute values of negative elements, and store the positive matrix and the negative matrix in the global buffer 313, in operation S105. The positive matrix and the negative matrix, stored in the global buffer 313, may be separately stored in a first sub array and a second sub array, respectively.

When a negative element is included in the vector serving as the second operand (Y (vector) in operation S103), the negative number computation control circuit 500 may determine an offset for converting the negative element, which has the largest absolute value among the elements of the vector, into a non-negative element, i.e., a zero element or a positive element, and add the offset to each of the elements of the vector, thereby generating an offset vector, in operation S107. The offset vector may be applied to row lines of the first and second sub arrays in which the positive matrix and the negative matrix are respectively stored.

As the matrix values are stored in the first and second sub arrays and the offset vector is applied to the row lines, an in-memory VMM is performed while currents corresponding to the multiplications between the matrix (conductance) and the vector (voltage) are added up for each column line, in operation S109.

As the VMM result, a positive computation value may be outputted from the first sub array, and a negative computation value may be outputted from the second sub array. Since the VMM has been performed on the absolute values of the negative elements included in the matrix, the computation results are combined by subtracting the negative computation value from the positive computation value, in operation S111.

In an embodiment, in order to combine the computation results, the positive computation value and the negative computation value may be converted into digital values, respectively, and subtraction may be performed on the digital values by a digital subtractor. In another embodiment, in order to combine the computation results, the negative computation value may be subtracted from the positive computation value by an analog subtractor, and the subtraction result may be converted into a digital value,

When the VMM is performed through the offset vector obtained by applying the offset to the vector, the negative number computation control circuit 500 may derive the final computation result by correcting the VMM result according to the offset, in operation S113. For example, the negative number computation control circuit 500 may calculate a first correction value as the VMM result between the offset and the positive matrix and a second correction value as the VMM result between the offset and the negative matrix, and derive an offset correction value by subtracting the second correction value from the first correction value. Then, the negative number computation control circuit 500 may acquire the final computation result by subtracting the offset correction value from the computation result combined in operation S111.

The final computation result may be outputted to the global buffer 313 in operation S115.

When neither of the first and second operands include negative elements (N in operation S103), the operands may be provided to the computation memory 311 to perform VMM in operation S117, and the VMM result may be outputted to the global buffer 313 in operation S115.

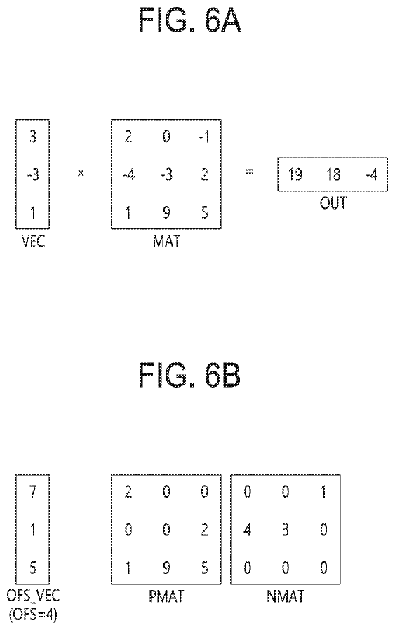

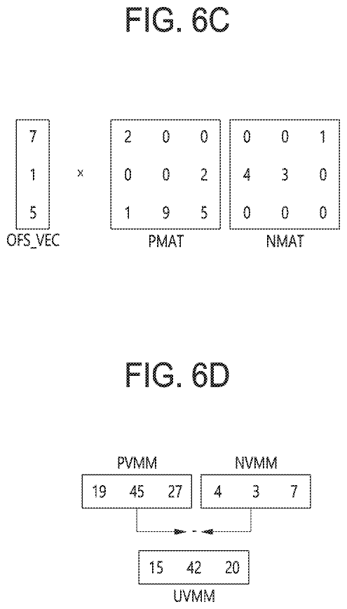

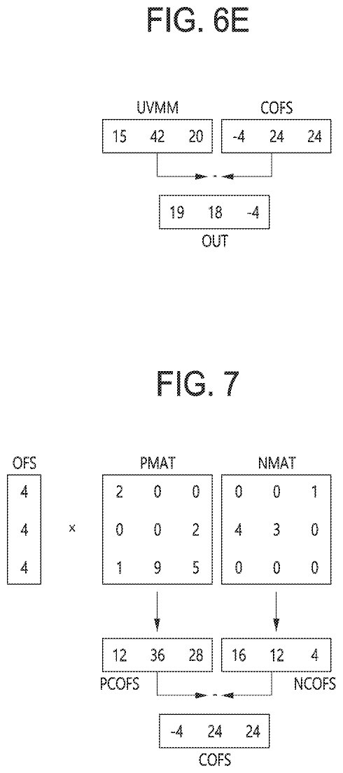

FIGS. 6A to 6E are conceptual views for describing a VMM including negative elements in accordance with an embodiment of the present disclosure.

FIGS, 6A to 6E illustrate that an operand, an intermediate computation value, and a final computation result are decimal numbers. However, the actual computation in the data processing system 200 is performed on the basis of binary numbers or hexadecimal numbers. In FIGS. 6A to 6E, each of the vectors VEC, OFS_VEC is a 1×N vector (i.e., a row vector) even though illustrated like a column vector.

FIG. 6A illustrates a process of performing a VMM on a first operand MAT and a second operand VEC,

Since the matrix MAT serving as the first operand includes negative elements, the negative number computation control circuit 500 may split the matrix MAT into a positive matrix PMAT composed of positive elements and a negative matrix NMAT composed of the absolute values of negative elements as Illustrated in FIG. 6B, and then store the positive matrix PMAT and the negative matrix NMAT in the global buffer 313. The positive matrix PMAT and the negative matrix NMAT, stored in the global buffer 313, may be separately stored in the first sub array and the second sub array, respectively.

When a negative element is included in the vector VEC serving as the second operand, the negative number computation control circuit 500 determines an offset for converting the negative element (−3), which has the largest absolute value among the elements of the vector, into a non-negative element, i.e., a zero element or a positive element. As illustrated in FIG. 6B, the negative number computation control circuit 500 may determine an offset OFS as 4, and generate an offset vector OFS_VEC by adding the offset to each of the elements of the vector. The offset vector may be applied to row lines of the first and second sub arrays in which the positive matrix and the negative matrix are respectively stored.

As the matrix values are stored in the first and second sub arrays and the offset vector is applied to the row lines, an in-memory VMM is performed while currents corresponding to the multiplications between the matrix (conductances) and the vector (voltages) are added up for each column line as illustrated in FIG. 6C.

FIG. 6D illustrates that a combined computation result UVMM is derived by subtracting a negative computation value NVMM, outputted as the VMM result from the second sub array, from a positive computation value PVMM outputted as the VMM result from the first sub array.

Since the VMM has been performed through the offset vector OFS_VEC obtained by adding the offset OFS to the vector VEC, the negative number computation control circuit 500 drives a final computation result OUT by subtracting the offset correction value COF from the combined computation result UVMM as illustrated in FIG. 6E.

FIG. 7 is a conceptual view for describing an offset correction value generation method in accordance with an embodiment of the present disclosure.

In order to generate the offset correction value COF, the negative number computation control circuit 500 calculates a first correction value PCOFS as the VMM result between the offset OFS and the positive matrix PMAT and a second correction value NCOFS as the VMM result between the offset OFS and the negative matrix NMAT. By subtracting the second correction value NCOFS from the first correction value PCOFS, the negative number computation control circuit 500 may derive the offset correction value COFS. As illustrated in FIG. 6E, the negative number computation control circuit 500 derives the final computation result OUT by subtracting the offset correction value COF from the combined computation result UVMM.

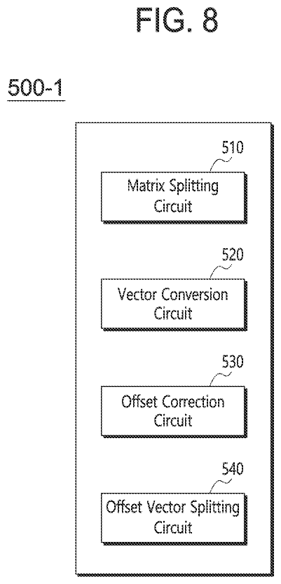

FIG. 8 is a configuration diagram illustrating the negative number computation control circuit in accordance with an embodiment of the present disclosure.

Referring to FIG. 8, a negative number computation control circuit 500-1 may include a matrix splitting circuit 510, a vector conversion circuit 520, an offset vector splitting circuit 540, and an offset correction circuit 530.

When the first operand which is a matrix generated as an intermediate computation result of the host device 100 or the computation memory 311 includes negative elements, the matrix splitting circuit 510 may split the elements constituting the matrix into a positive matrix composed of positive elements and a negative matrix composed of the absolute values of negative elements, and store the positive matrix and the negative matrix in the global buffer 313.

When negative elements are included in the vector serving as the second operand, the vector conversion circuit 520 may determine an offset for converting the negative element, which has the largest absolute value among the elements of the vector, into a non-negative element, and add the offset to each of the elements of the vector, thereby generating an offset vector.

The offset vector splitting circuit 540 may generate a sequential vector VEC_SEQ including one or more partial offset vectors by splitting elements constituting the offset vector on a bitwise basis according to place values. For example, when each element of the offset vector is a binary number composed of a X bits where X is a positive integer, the offset vector splitting circuit 540 may split each of elements constituting the offset vector corresponding to the 2^{M} place of the offset vector (M is 0 or a positive integer between 1 and X) and generate the partial offset vectors. The sequential vector VEC_SEQ may be configured as a plurality of partial offset vectors.

The partial offset vectors may be sequentially provided to the first and second sub arrays by the vector conversion circuit 520, and subjected to the VMM with the positive matrix and the negative matrix.

As the offset is determined by the vector conversion circuit 520, the offset correction circuit 530 may calculate a first correction value as the VMM result between the positive matrix and the offset and a second correction value as the VMM result between the negative matrix and the offset, and derive an offset correction value by subtracting the second correction value from the first correction value. As a positive computation value acquired by the positive matrix and the partial offset vectors provided sequentially and a negative computation value acquired by the negative matrix and the partial offset vectors provided sequentially are combined and outputted by the computation memory 311, the offset correction circuit 530 may calculate the final computation result by subtracting the offset correction value from the combined computation result.

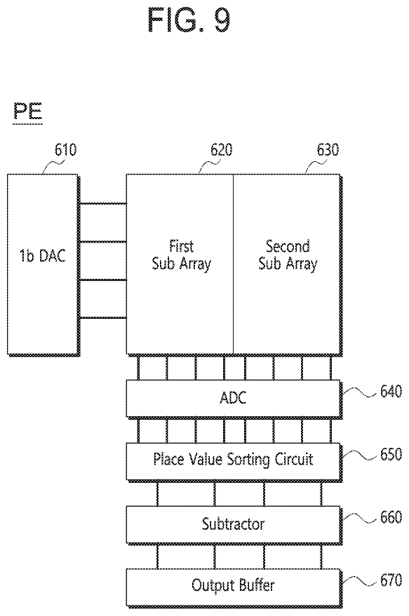

FIG. 9 is a configuration diagram illustrating the processing element in accordance with an embodiment of the present disclosure.

Referring to FIG. 9, a processing element PE in accordance with an embodiment may include a 1-bit Digital-Analog Converter (DAC) 610, a first sub array 620, a second sub array 630, an ADC 640, a place value sorting circuit 650, a subtractor 660, and an output buffer 670.

The 1-bit DAC 610 is configured to convert the partial offset vectors generated by the offset vector splitting circuit 540 into analog values, and apply the analog values to row lines of the first and second sub arrays 620 and 630.

The first sub array 620 may store a positive matrix therein, and the second sub array 630 may store a negative matrix therein. Partial positive computation values between the positive matrix and the partial offset vectors which are sequentially applied are sequentially outputted from the first sub array 620. Partial negative computation values between the negative matrix and the partial offset vectors which are sequentially applied are sequentially outputted from the second sub array 630.

The ADC 640 may convert the partial positive computation values, which are sequentially outputted from the first sub array 620, into digital values, and convert the partial negative computation values, which are sequentially outputted from the second sub array 630, into digital values.

The place value sorting circuit 650 may sort the partial positive computation values and the partial negative computation values, which are sequentially outputted from the ADC 640, according to the place values of the partial offset vector, and add up the computation results whose place values are aligned.

For example, when each element of the offset vector is composed of X bits where X is a positive integer, the place value sorting circuit 650 may convert the partial positive computation value and the partial negative computation value for the partial offset vector corresponding to the 2^{M} place of the offset vector (M is 0 or a positive integer between 1 and X) into 2^{M} place values. Then, the place value sorting circuit 650 may add up all the partial positive computation values whose place values are sorted and output the positive computation value, and add up all the partial negative computation values whose place values are sorted and output the negative computation value.

The subtractor 660 may subtract the negative computation value from the positive computation value, and store the subtraction result in the output buffer 670, In an embodiment, the subtractor 660 may convert the negative computation value into a negative number by converting the negative computation value into a complementary number of 2, and add the negative number to the positive computation value,

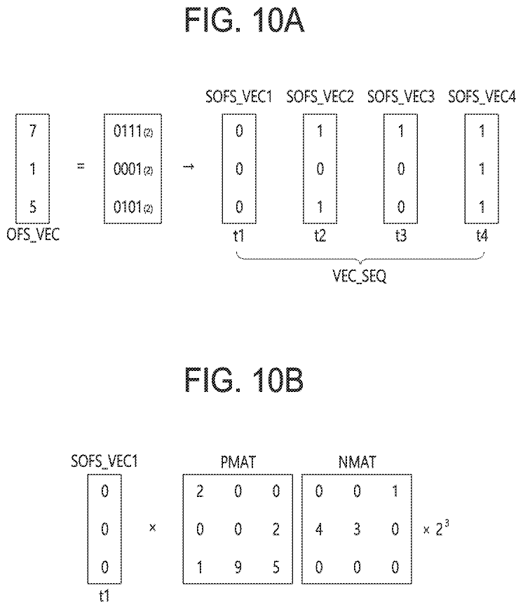

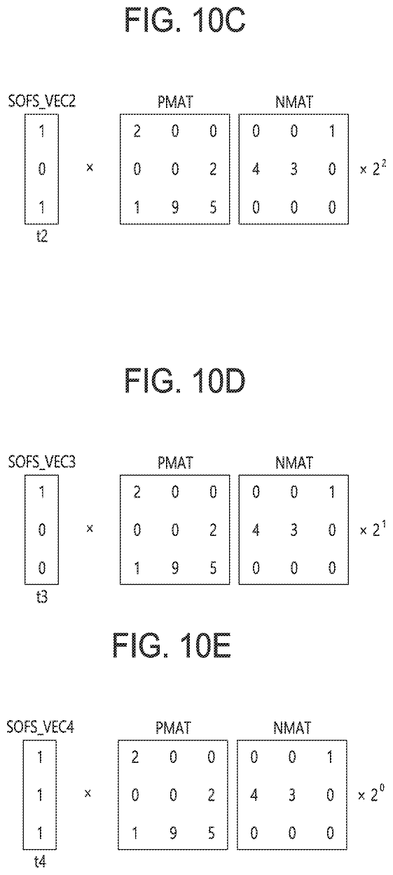

FIGS. 10A to 10E are conceptual views for describing an offset vector providing method in accordance with an embodiment of the present disclosure. In FIGS. 10A to 10E, each of the vectors OFS_VEC and SOFS_VECx is an 1×N vector (a row vector) even though illustrated like a column vector.

The elements (7, 1, 5) of the offset vector OFS_VEC generated as illustrated in FIG. 63 may be each expressed as a 4-bit binary number as illustrated in FIG, 10A, and the offset vector splitting is circuit 540 configures a sequential vector VEC_SEQ by splitting the offset vector OFS_VEC on a bitwise basis according to the place values. That is, the sequential vector VEC_SEQ may be configured as a plurality of partial offset vectors SOFS_VEC1, SOFS_VEC2, SOFS_VEC3, and SOFS_VEC4.

The partial offset vectors SOFS_VEC1, SOFS_VEC2, SOFS_VEC3, and SOFS_VEC4 constituting the sequential vector VEC_SEQ are sequentially provided to the first sub array 620 and the second sub array 630 in which the positive matrix PMAT and the negative matrix NMAT are respectively stored.

The place value sorting circuit 650 may sort partial positive computation values between the partial offset vectors SOFS_VEC1, SOFS_VEC2, SOFS_VEC3, and SOFS_VEC4 and the positive matrix and partial negative computation values between the partial offset vectors SOFS_VEC1, SOFS_VEC2, SOFS_VEC3, and SOFS_VEC4 and the s negative matrix, according to the place values of the partial offset vectors SOFS_VEC1, SOFS_VEC2, SOFS_VEC3, and SOFS_VEC4.

As illustrated in FIG. 10B, the first partial offset vector SOFS_VEC1 is applied to the row lines of the first and second sub arrays 620 and 630 to perform a VMM at a first time point ti. Since the first partial offset vector SOFS_VEC1 corresponds to the 2³ place of the offset vector OFS_VEC, the place value sorting circuit 650 sorts the partial positive computation value and the partial negative computation value for the first partial offset vector SOFS_VEC1 into values corresponding to the 2³ place,

As illustrated in FIG. 10C, the second partial offset vector SOFS_VEC2 is applied to the row lines of the first and second sub arrays 620 and 630 to perform a VMM at a second time point t2. Since the second partial offset vector SOFS_VEC2 corresponds to the 2² place of the offset vector OFS_VEC, the place value sorting circuit 650 sorts the partial positive computation value and the partial negative computation value for the second partial offset vector SOFS_VEC2 into values corresponding to the 2³ place.

As illustrated in FIG. 10D, the third partial offset vector SOFS_VEC3 is applied to the row lines of the first and second sub arrays 620 and 630 to perform a VMM at a third time point t3. Since the third partial offset vector SOFS_VEC3 corresponds to the 2¹ place of the offset vector OFS_VEC, the place value sorting circuit 650 sorts the partial positive computation value and the partial negative computation value for the third partial offset vector SOFS_VEC3 into values corresponding to the 2¹ place.

As illustrated in FIG. 10E, the fourth partial offset vector SOFS_VEC4 is applied to the row lines of the first and second sub arrays 620 and 630 to perform a VMM at a fourth time point t4. Since the fourth partial offset vector SOFS_VEC4 corresponds to the 2⁰ place of the offset vector OFS_VEC, the place value sorting circuit 550 sorts the partial positive computation value and the partial negative computation value for the fourth partial offset vector SOFS_VEC4 into values corresponding to the 2⁰ place.

After the place values are sorted, the place value sorting circuit 650 may add up all the partial positive computation values for the positive matrix and output the positive computation value, and add up all the partial negative computation values for the negative matrix and output the negative computation value.

As described above, after the positive computation value and the negative computation value are combined, the final computation result may be calculated by subtracting the offset correction value from the combined computation result.

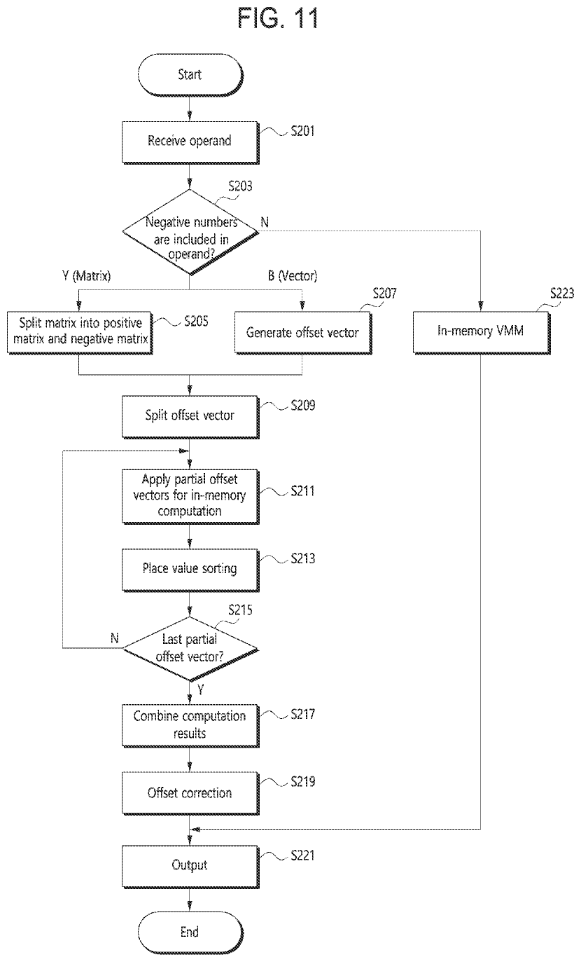

FIG. 11 is a flowchart for describing an operating method of a data processing system in accordance with an embodiment of the present disclosure.

As a first operand and a second operand are provided to the neural network processor 300 of the data processing system 200 in operation S201, the negative number computation control circuit 500 may check whether a negative element is included in the first operand s and/or the second operand in operation S203.

When a negative element is included in a matrix serving as the first operand (Y (matrix) in operation S203), the negative number computation control circuit 500 may split elements constituting the matrix into a positive matrix composed of positive elements and a negative matrix composed of the absolute values of negative elements, and store the positive matrix and the negative matrix in the global buffer 313, in operation S205. The positive matrix and the negative matrix, stored in the global buffer 313, may be separately stored in the first sub array and the second sub array, respectively.

When a negative element is included in a vector serving as the second operand (Y (vector) in operation S203), the negative number computation control circuit 500 may determine an offset for converting the negative element, which has the largest absolute value among the elements of the vector, into a non-negative element, i.e., a zero element or a positive element, and add the offset to each of the elements of the vector, thereby generating an offset vector, in operation S207.

The negative number computation control circuit 500 may generate a sequential vector composed of one or more partial offset vectors by splitting each of the elements constituting the offset vector on a bitwise basis according to the place values, in operation S209.

The partial offset vector may be sequentially provided to the first and second sub arrays from the Most Significant Bit (MSB), for example, and subjected to VMM with the positive matrix and the negative matrix, respectively, in operation S211.

As the partial offset vectors which are sequentially provided are subjected to the VMM with the positive matrix and the negative matrix and converted into digital values, the place value sorting circuit 650 sorts the partial positive computation values and the partial negative computation values, which are sequentially outputted, according to the place values of the partial offset vectors, in operation 5213.

The negative number computation control circuit 500 checks whether there are partial offset vectors which are not yet inputted, or whether the partial offset vector processed at the previous point of time is the last partial offset vector, in operation S215. When the check result indicates that the last partial offset vector is not yet processed (N in operation S215), the negative number computation control circuit 500 applies the partial offset vector of the next place value to the first sub array 620 and the second sub array 630, such that in-memory computation is performed, in operation S211. When the computation value for the last partial offset vector is calculated (Y in operation S215), the negative number computation control circuit 500 derives a positive computation value by adding up all partial positive computation values whose place values are sorted, derives a negative computation value by adding up all partial negative computation values whose place values are sorted, and then combines the positive computation value and the negative computation value, in operation S217. The operations S209 to S214 may be applied for the operation of applying the offset vector described in FIG. 5.

In an embodiment, in order to combine the computation values, the negative number computation control circuit 500 may convert the positive computation value and the negative computation value into digital values, convert the negative computation value into a complementary number of 2, and then add the complementary number to the positive computation value. In another embodiment, in order to combine the computation results, the negative computation value may be subtracted from the positive computation value by an analog subtractor, and the subtraction result may be then converted into a digital value.

When the VMM is performed through the offset vector obtained by applying the offset to the vector, the negative number computation control circuit 500 may derive the final computation result by correcting the VMM result according to the offset, in operation S219. For example, the negative number computation control circuit 500 may calculate a first correction value as the VMM result between the offset and the positive matrix and a second correction value as the VMM result between the offset and the negative matrix, and derive an offset correction value by subtracting the second correction value from the first correction value. Then, the negative number computation control circuit 500 may acquire the final computation result by subtracting the offset correction value from the computation result combined in operation S217.

The final computation result may be outputted to the global buffer 313 in operation S221.

When neither of the first and second operands include negative elements (N in operation S203), the operands may be provided to the computation memory 311 to perform the VMM in operation S223, and the VMM result may be outputted to the global buffer 313 in operation S221.

Even when a vector or matrix serving as an operand includes a negative element in a cross-bar array in which an analog computation is performed through resistance and voltage, negative number computation can be performed in a simple manner without increasing the system complexity, which makes it possible to efficiently perform the neural network computation.

As such, the person skilled in the art can appreciate that the present disclosure can be carried out in other specific forms without changing the technical spirit or essential features of the present disclosure. Therefore, it should be understood that the embodiments described above are not restrictive but illustrative in all aspects. The scope of the present disclosure is defined by the claims to be described below rather than the detailed description, and all the changed or modified forms derived from the meaning and scope of the claims and the equivalent concept thereto should be construed as being included in the scope of the present disclosure. Furthermore, the embodiments may be combined to form additional embodiments.

What is claimed is:

1. A data processing system comprising:
a computation memory comprising one or more sub arrays each including a plurality of memory cells coupled between a plurality of row lines and a plurality of column lines;
a matrix splitting circuit configured to:
split, when negative elements are included in a matrix received from a host device, the matrix into a positive matrix composed of positive elements from the matrix and a negative matrix composed of absolute values of the negative elements from the matrix, and
store the positive matrix and the negative matrix in a first sub array and a second sub array within the computation memory, respectively;
is a vector conversion circuit configured to:
generate, when negative elements are included in a vector received from the host device, an offset vector by adding, to elements within the vector, an offset for converting a negative element, which has a largest absolute value among the elements within the vector, into a zero element or a positive element, and
apply the offset vector to the row lines of the first sub array and the second sub array; and
an offset correction circuit configured to:
generate an offset correction value by subtracting a result of multiplying the offset and the negative matrix from a result of multiplying the offset and the positive matrix, and
subtract the offset correction value from a computation value outputted from the first sub array and the second sub array.

2. The data processing system according to claim 1, wherein the computation memory is configured to generate the computation value by subtracting a negative computation value, which is outputted from the second sub array as a result of multiplying the negative matrix and the offset vector, from a positive computation value, which is outputted from the first sub array as a result of multiplying the positive matrix and the offset vector.

3. The data processing system according to claim 2, wherein the computation memory further comprises:
an analog-digital converter configured to convert the positive computation value and the negative computation value respectively into a digitalized positive computation value and a digitalized negative computation value; and
a digital subtractor configured to subtract the digitalized negative computation value from the digitalized positive computation value to generate the computation value.

4. The data processing system according to claim 2, wherein the computation memory further comprises:
an analog subtractor configured to subtrac the negative computation value from the positive computation value; and
an analog-digital converter configured to convert an output of the analog subtractor to generate the computation value.

5. The data processing system according to claim 1,
wherein each of elements constituting the offset vector is a binary number composed of a plurality of bits,
further comprising an offset vector splitting circuit configured to:
generate a sequential vector including one or more partial offset vectors by splitting the offset vector on a bitwise basis according to place values, and
the vector conversion circuit is configured to sequentially apply the partial offset vectors to the row lines of the first and second sub arrays.

6. The data processing system according to claim 5, wherein the computation memory further comprises a place value sorting circuit configured to
sort, according to the place values of the partial offset vectors, partial positive computation values as results of multiplying the partial offset vectors and the positive matrix,
sort, according to the place values of the partial offset vectors, partial negative computation values as results of multiplying the partial offset vectors and the negative matrix,
derive a positive computation value by adding up all sorted partial positive computation values, and
derive a negative computation value by adding up all sorted partial negative computation values.

7. An operating method of a data processing system, comprising:
providing a computation memory comprising one or more sub arrays each including a plurality of memory cells coupled between a plurality of row lines and a plurality of column lines;
splitting, by a negative number computation control circuit, when negative elements are included in a matrix received from a host device, the matrix into a positive matrix composed of positive elements from the matrix and a negative matrix composed of absolute values of the negative elements from the matrix;
storing the positive matrix and the negative matrix in a first sub array and a second sub array within the computation memory, respectively;
generating, by the negative number computation control circuit, when negative elements are included in a vector received from the host device, an offset vector by adding, to elements within the vector, an offset for converting a negative element, which has a largest absolute value among the elements within the vector, into a zero element or a positive element;
applying, by the negative number computation control circuit, the offset vector to the row lines of the first sub array and the second sub array;
generating, by the negative number computation control circuit, an offset correction value by subtracting a result of multiplying the offset and the negative matrix from a result of multiplying the offset and the positive matrix; and
subtracting, by the negative number computation control circuit, the offset correction value from a computation value outputted from the first and second sub arrays,

8. The operating method according to claim 7, further comprising generating the computation value by subtracting a negative computation value, which is outputted from the second sub array as a result of multiplying the negative matrix and the offset vector, from a positive computation value, which is outputted from the first sub array as a result of multiplying the positive matrix and the offset vector.

9. The operating method according to claim 8, wherein the generating of the computation value includes:
converting, by the computation memory, the positive computation value and the negative computation value respectively into a digitalized positive computation value and a digitalized negative computation value; and
generating, by the computation memory, the computation value by subtracting the digitalized negative computation value from the digitalized positive computation value.

10. The operating method according to claim 8, wherein the generating of the computation value includes:
subtracting the negative computation value from the positive computation value; and
generating the computation value by converting an output of an analog subtractor into a digital value.

11. The operating method according to claim 7,
wherein each element constituting the offset vector is a binary number composed of a plurality of bits,
wherein the applying the offset vector includes:
generating a sequential vector including one or more partial offset vectors by splitting the offset vector on a bitwise basis according to place values; and
sequentially applying the partial offset vectors to the row lines of the first and second sub arrays.

12. The operating method according to claim 11, further comprising:
sorting, according to the place values of the partial offset vectors, partial positive computation values as results of multiplying the partial offset vectors and the positive matrix;
sorting, according to the place values of the partial offset vectors, partial negative computation values as results of multiplying the partial offset vectors and the negative matrix;
deriving a positive computation value by adding all the sorted partial positive computation values; and
deriving a negative computation value by adding all the sorted partial negative computation values,

13. A computing system comprising:
a host device;
a data processing system configured to process a computation of an application according to a request of the host device, and comprising a computation memory including one or more sub arrays each including a plurality of memory cells coupled between a plurality of row lines and a plurality of column lines; and
a negative number computation control circuit configured to
split, when negative elements are included in a matrix received from the host device, the matrix into a positive matrix and a negative matrix,
generate, when negative elements are included in a vector received from the host device, an offset vector by adding an offset to the vector, and
correct a computation value, outputted as a result of multiplying each of the positive and negative matrices with the offset vector, from the computation memory according to an offset correction value generated on the basis of the offset.

14. The computing system according to claim 13, wherein the sub arrays comprise:
a first sub array configured to store the positive matrix therein and receive the offset vector through the row lines thereof; and
a second sub array configured to store the negative matrix therein and receive the offset vector through the row lines thereof.

15. The computing system according to claim 13, wherein the negative number computation control circuit is further configured to generate the offset correction value by subtracting a result of multiplying the offset and the negative matrix from a result of multiplying the offset and the positive matrix.

16. The computing system according to claim 13, wherein the computation memory is configured to generate the computation value by subtracting a negative computation value, which is outputted from a second sub array as a result of multiplying the negative matrix and the offset vector, from a positive computation value, which is outputted from a first sub array as a result of multiplying the positive matrix and the offset vector.

17. The computing system according to claim 13, wherein the negative number computation control circuit is further configured to subtract the offset correction value from the computation value.

18. The computing system according to claim 13,
wherein each element constituting the offset vector is a binary number composed of a plurality of bits,
wherein the negative number computation control circuit is further configured to:
generate a sequential vector including one or more offset vectors by splitting the offset vector on a bitwise basis according to place values, and
sequentially apply the partial offset vectors to the row lines of sub arrays in which the positive matrix and the negative matrix are respectively stored.

19. The computing system according to claim 18, wherein the computation memory is further configured to:
sort, according to the place values of the partial offset vectors, partial positive computation values as results of multiplying the partial offset vectors and the positive matrix,
sort, according to the place values of the partial offset vectors, partial negative computation values as results of multiplying the part offset vectors and the negative matrix, and
subtract the sorted partial negative computation values from the sorted partial positive computation values.
